(19) United States
(12) Patent Application Publication
(10) Pub. No.: US 2026/0369530 A1
(43) Pub. Date: Nov. 19, 2026

(54) RADIO FREQUENCY POWER SUPPLY FOR PLASMA GENERATION AND PLASMA PROCESSING APPARATUS

(71) Applicants: Tokyo Electron Limited, Tokyo (JP); Fukuoka University, Fukuoka-shi (JP)

(72) Inventors: Rei MIZOGUCHI, Nirasaki City (JP); Kazushi KANEKO, Nirasaki City (JP); Ryo SHIMAZU, Nirasaki City (JP); Masaki DOBASHI, Nirasaki City (JP); Shin OOWADA, Tokyo (JP); Tadashi SUETSUGU, Fukuoka-shI (JP)

(21) Appl. No.: 19/669,162

(22) Filed: May 6, 2026

(30) Foreign Application Priority Data
May 13, 2025 (JP) 2025-080481

(51) Int. Cl. H01J 37/32

(52) U.S. Cl. CPC H01J 37/32183; H01J 37/32091; H01J 37/32155; H01J 2237/327

(57) ABSTRACT

A radio frequency power supply for plasma generation includes: an amplifier having a gate terminal, a drain terminal, and a source terminal; an input power supply electrically connected to the gate terminal to supply input power to the amplifier, and configured to vary a supply frequency of the input power within an available supply frequency band; an output terminal electrically connected to the drain terminal; an input-side transformer circuit connected between the input power supply and the gate terminal; and an output-side transformer circuit connected between the drain terminal and the output terminal.

### CROSS-REFERENCE TO RELATED APPLICATION

This application is based upon and claims the benefit of priority from Japanese Patent Application No. 2025-080481, filed on May 13, 2025, the entire content of which is incorporated herein by reference.

### TECHNICAL FIELD

The present disclosure relates to a radio frequency power supply for plasma generation and a plasma processing apparatus.

### BACKGROUND

Patent Document 1 discloses that “a combined pi-type impedance matching circuit 108a configured by a series circuit of a high-pass filter 201 and a low-pass filter 202 is additionally connected to an impedance conversion circuit 109 of a conventional circuit, and an impedance matching circuit 108 obtained by combining a capacitor C21 of the pi-type impedance matching circuit 108a with an output circuit capacitor C18 of the impedance conversion circuit 109 is used as an output circuit of a radio frequency multiplication and amplification circuit.”

### PRIOR ART DOCUMENT

### Patent Document

Patent Document 1: Japanese Patent Laid-open Publication No. 2005-101964

### SUMMARY

A radio frequency power supply for plasma generation according to the present disclosure includes an amplifier, an input power supply, an output terminal, an input-side transformer circuit, and an output-side transformer circuit. The amplifier has a gate terminal, a drain terminal, and a source terminal. The input power supply is electrically connected to the gate terminal to supply input power to the amplifier, and is configured to vary a supply frequency of the input power within an available supply frequency band. The output terminal is electrically connected to the drain terminal. The input-side transformer circuit is connected between the input power supply and the gate terminal. The output-side transformer circuit is connected between the drain terminal and the output terminal.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a configuration of a plasma processing apparatus according to one embodiment of the present disclosure.

FIG. 2 is a block diagram illustrating an example of a functional configuration of a first radio frequency power supply according to the embodiment.

FIG. 3 is a diagram illustrating an example of impedance conversion by a transformer.

FIG. 4 is a diagram illustrating an example of an input-side transformer circuit according to the embodiment.

FIG. 5 is a diagram illustrating an example of an output-side transformer circuit according to the embodiment.

FIG. 6 is a diagram illustrating an example of an input-side pi-type matching circuit according to a reference example.

FIG. 7 is a diagram illustrating an example of an output-side pi-type matching circuit according to a reference example.

FIG. 8 is a graph illustrating an example of frequency characteristics of an input-side circuit.

FIG. 9 is a graph illustrating an example of frequency characteristics of an output-side circuit.

FIG. 10 is a graph illustrating an example of efficiencies of the first radio frequency power supply when a coupling index S is constant and a coupling coefficient k and a frequency are variable.

FIG. 11 is a graph illustrating an example of outputs of the first radio frequency power supply when the coupling index S is constant and the coupling coefficient k and the frequency are variable.

FIG. 12 is a graph illustrating an example of efficiencies of the first radio frequency power supply when the coupling coefficient k is constant and the coupling index S and the frequency are variable.

FIG. 13 is a graph illustrating an example of outputs of the first radio frequency power supply when the coupling coefficient k is constant and the coupling index S and the frequency are variable.

FIG. 14 is a graph illustrating an example of a range of an optimal value of the coupling coefficient k within which the efficiencies become 70% or more when the coupling index S is constant and the coupling coefficient k and the frequency are variable.

FIG. 15 is a graph illustrating an example of a range of an optimal value of the coupling coefficient k within which the outputs become 1,000 W or more when the coupling index S is constant and the coupling coefficient k and the frequency are variable.

FIG. 16 is a graph illustrating an example of a range of an optimal value of the coupling index S within which the efficiencies become 70% or more when the coupling coefficient k is constant and the coupling index S and the frequency are variable.

FIG. 17 is a graph illustrating an example of a range of an optimal value of the coupling index S within which the outputs become 1,000 W or more when the coupling coefficient k is constant and the coupling index S and the frequency are variable.

FIG. 18 is a graph illustrating an example of a relationship between a center frequency and a degree of improvement in efficiency.

FIG. 19 is a graph illustrating an example of a relationship between a frequency and an output.

FIG. 20 is a graph illustrating an example of a relationship between a frequency and an efficiency.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a radio frequency power supply for plasma generation and a plasma processing apparatus disclosed herein will be described in detail with reference to the drawings. In addition, the disclosed technique is not limited by the following embodiments.

In a plasma processing apparatus, a power amplifier using, for example, a field effect transistor (FET) is used in a radio frequency (RF) power supply. Such a power amplifier adopts a pi-type circuit to match an impedance of the FET with an input impedance and an output impedance of the power amplifier. Further, in the RF power supply, impedance matching may be performed by frequency variation in order to suppress reflected waves caused by impedance mismatch during plasma generation. However, in the pi-type circuit, when the frequency of the radio frequency power varies from a fundamental frequency, efficiency of the power amplifier may be reduced, and an output of the radio frequency power may be reduced. Therefore, reducing loss in the power amplifier when performing impedance matching by frequency variation during plasma generation is desired.

### [Configuration of Plasma Processing Apparatus 1]

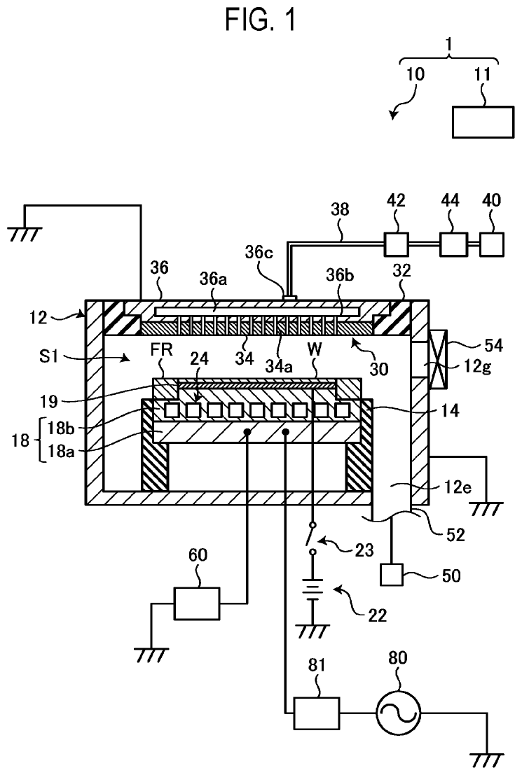

FIG. 1 is a schematic cross-sectional view illustrating an example of a configuration of a plasma processing apparatus according to one embodiment of the present disclosure. The plasma processing apparatus 1 illustrated in FIG. 1 is configured as a plasma processing apparatus using capacitively coupled plasma (CCP). The plasma processing apparatus 1 includes an apparatus main body 10 and a controller 11 that controls the entire plasma processing apparatus 1. Further, the apparatus main body 10 includes a substantially cylindrical processing container 12, a first radio frequency power supply 60, and a second radio frequency power supply 80.

An inner wall surface of the processing container 12 is made of, for example, anodized aluminum. The processing container 12 is grounded for safety. A substantially cylindrical support 14 is provided on a bottom of the processing container 12. The support 14 is made of, for example, an insulating material. The support 14 extends in the processing container 12 in a vertical direction from the bottom of the processing container 12. Further, a lower electrode 18 that functions as a stage for a substrate W is provided in the processing container 12. The lower electrode 18 is supported by the support 14. In addition, a wafer is an example of the substrate W.

The lower electrode 18 holds the substrate W on an upper surface of the lower electrode 18. The lower electrode 18 includes a first plate 18a and a second plate 18b. The first plate 18a and the second plate 18b are, for example, made of a metal such as aluminum and have a substantially disk shape. The second plate 18b is provided on the first plate 18a and is electrically connected to the first plate 18a.

An electrostatic chuck 19 is provided on the second plate 18b of the lower electrode 18. The electrostatic chuck 19 has a structure in which an electrode, which is a conductive film, is disposed between a pair of insulating layers or insulating sheets. A direct current (DC) power supply 22 is electrically connected to the electrode of the electrostatic chuck 19 via a switch 23. The electrostatic chuck 19 attracts the substrate W by electrostatic force such as Coulomb force generated by a DC voltage from the DC power supply 22. This allows the electrostatic chuck 19 to hold the substrate W.

A focus ring FR is disposed on a peripheral portion of the second plate 18b of the lower electrode 18, so as to surround an edge of the substrate W and the electrostatic chuck 19. The focus ring FR is provided to improve uniformity of etching. The focus ring FR is made of a material appropriately selected according to a material of a film to be etched, and may be made of, for example, quartz. In addition, the focus ring FR is an example of an edge ring.

A coolant flow path 24 is provided in an interior of the second plate 18b. The coolant flow path 24 constitutes a temperature adjuster. A heat transfer fluid such as brine or gas flows through the coolant flow path 24. For example, a coolant, which is supplied from a chiller provided outside the processing container 12, circulates through the coolant flow path 24. By controlling a temperature of the coolant, a temperature of the substrate W supported by the electrostatic chuck 19 is controlled. Further, the lower electrode 18 may include a heat transfer gas supplier configured to supply a heat transfer gas to a gap between a back surface of the substrate W and an upper surface of the electrostatic chuck 19.

Further, the apparatus main body 10 includes an upper electrode 30. The upper electrode 30 is disposed above the lower electrode 18 to face the lower electrode 18. The lower electrode 18 and the upper electrode 30 are provided substantially parallel to each other. A processing space S1 for performing plasma processing on the substrate W is provided between the upper electrode 30 and the lower electrode 18.

The upper electrode 30 is supported at an upper portion of the processing container 12 via an insulating shield 32. Further, the upper electrode 30 is grounded. The upper electrode 30 may include an electrode plate 34 and an electrode support 36. The electrode plate 34 faces the processing space S1, and a plurality of gas discharge holes 34a are provided in the electrode plate 34. The electrode plate 34 is made of, for example, silicon.

The electrode support 36 detachably supports the electrode plate 34 and may be made of, for example, a conductive material such as aluminum. The electrode support 36 may have a water-cooling structure. A gas diffusion chamber 36a is provided in an interior of the electrode support 36. A plurality of gas flow holes 36b extend downward from the gas diffusion chamber 36a to communicate with the gas discharge holes 34a. Further, a gas introduction port 36c is formed in the electrode support 36 to introduce a processing gas into the gas diffusion chamber 36a, and a gas supply pipe 38 is connected to the gas introduction port 36c.

A gas source group 40 is connected to the gas supply pipe 38 via a valve group 42 and a flow-rate controller group 44. The gas source group 40 includes a plurality of gas sources such as a source of a fluorocarbon gas, a source of a rare gas (noble gas), and a source of oxygen (O₂) gas. The fluorocarbon gas is, for example, a gas including at least one of C₄F₆ gas or C₄F₈ gas. Further, the rare gas is a gas including at least one of various rare gases such as Ar gas and He gas.

The valve group 42 includes a plurality of valves, and the flow-rate controller group 44 includes a plurality of flow-rate controllers such as mass flow controllers. Each of the plurality of gas sources in the gas source group 40 is connected to the gas supply pipe 38 via a corresponding valve in the valve group 42 and a corresponding flow-rate controller in the flow-rate controller group 44.

An exhaust port 12e is provided in the bottom of the processing container 12. An exhauster 50 is connected to the exhaust port 12e via an exhaust pipe 52. The exhauster 50 includes a vacuum pump such as a turbo molecular pump, and may depressurize a space in the processing container 12 to a desired degree of vacuum. Further, a load/unload port 12g for the substrate W is provided in a sidewall of the processing container 12, and can be opened and closed by a gate valve 54.

The controller 11 includes a memory, a processor, and an input/output interface. The memory stores a program executed by the processor and a recipe including data such as conditions of each processing. The processor executes the program read from the memory and controls individual components of the plasma processing apparatus 1 via the input/output interface based on the recipe stored in the memory.

For example, the controller 11 controls individual components of the plasma processing apparatus 1 to perform processing according to the recipe. As a detailed example, the controller 11 executes a step of setting process conditions, such as an internal pressure (degree of vacuum) of the processing container 12, a type and a flow rate of the processing gas, and an output of radio frequency power, with respect to individual components of the plasma processing apparatus 1 based on the recipe. The controller 11 executes a step of loading the substrate W to be processed into the processing container 12 and preparing the substrate W. The controller 11 executes a step of starting processing according to the recipe.

The first radio frequency power supply 60 outputs radio frequency power having a specific frequency which is within an available output frequency band. That is, the first radio frequency power supply 60 generates radio frequency power for plasma generation. The first radio frequency power supply 60 outputs radio frequency power having a specific frequency within a frequency band having a center frequency of, for example, 220 MHz. A set frequency F and a set power Pf of the radio frequency power are input to the first radio frequency power supply 60 from the controller 11. Further, the radio frequency power output from the first radio frequency power supply 60 is supplied to the lower electrode 18. Alternatively, the radio frequency power output from the first radio frequency power supply 60 may be supplied to the upper electrode 30.

The second radio frequency power supply 80 generates radio frequency power for drawing ions into the substrate W. The second radio frequency power supply 80 generates radio frequency power having a lower frequency than that of the radio frequency power generated by the first radio frequency power supply 60. The second radio frequency power supply 80 generates radio frequency power of 600 kHz, for example. Hereinafter, in order to distinguish the radio frequency power generated by the second radio frequency power supply 80 from the radio frequency power generated by the first radio frequency power supply 60, the radio frequency power generated by the second radio frequency power supply 80 is referred to as “radio frequency power for biasing.” The second radio frequency power supply 80 is connected to the lower electrode 18 via a matcher 81. The matcher 81 matches an output impedance of the second radio frequency power supply 80 with an input impedance of a load side (a lower electrode 18 side). The second radio frequency power supply 80 and the matcher 81, which are used for supplying the radio frequency power for biasing, may alternatively be a radio frequency power supply, which is provided separately from the first radio frequency power supply 60 and can vary a frequency of radio frequency power. Further, the second radio frequency power supply 80 may be omitted.

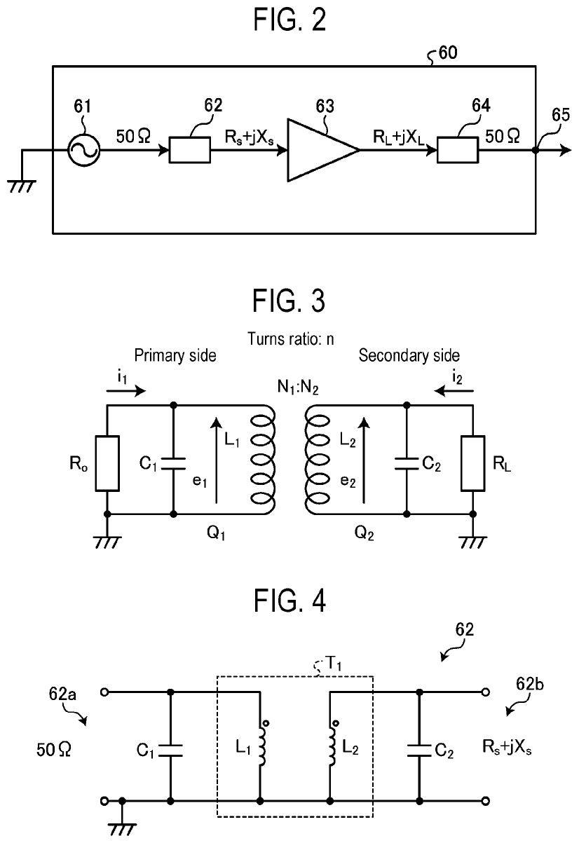

Next, details of the first radio frequency power supply 60 will be described with reference to FIG. 2. FIG. 2 is a block diagram illustrating an example of a functional configuration of the first radio frequency power supply according to the present embodiment. As illustrated in FIG. 2, the first radio frequency power supply 60 includes an input power supply 61, an input-side transformer circuit 62, an amplifier 63, and an output-side transformer circuit 64. The first radio frequency power supply 60 controls the input power supply 61 and the amplifier 63 based on the set frequency F and the set power Pf of the radio frequency power, which are input from the controller 11. An output terminal 65 of the first radio frequency power supply 60 is connected to the lower electrode 18. Further, a matcher (not illustrated) may be provided between the output terminal 65 and the lower electrode 18.

The input power supply 61 is, for example, an oscillator such as a direct digital synthesizer (DDS) or a voltage-controlled frequency generator (VF converter), and generates a radio frequency signal having the arbitrary set frequency F. The set frequency F input from the controller 11 includes, for example, a frequency and an amplitude (waveform data) of the radio frequency signal to be generated. The generated radio frequency signal is amplified by a preamplifier (not illustrated) and is output to the amplifier 63 via the input-side transformer circuit 62. In other words, the input power supply 61 is electrically connected to a gate terminal of the amplifier 63 to supply input power to the amplifier 63, and is configured to vary a supply frequency of the input power within an available supply frequency band. Further, the radio frequency signal output from the input power supply 61 is input power of the amplifier 63. For example, a center frequency of the input power supplied by the input power supply 61 is within a range of 10 MHz to 2,450 MHz. That is, a center frequency of radio frequency power output from the output terminal 65 is, for example, within a range of 10 MHz to 2,450 MHz. The center frequency is also referred to as a “fundamental frequency.”

The amplifier 63 amplifies the radio frequency signal input from the input power supply 61 via the input-side transformer circuit 62. The amplifier 63 outputs the amplified radio frequency signal from the output terminal 65 to the lower electrode 18 via the output-side transformer circuit 64. The amplifier 63 is an example of a switching amplification circuit and includes a field effect transistor (FET) having a gate terminal, a drain terminal, and a source terminal. The FET is an example of a transistor. That is, the amplifier 63 is an example of an amplifier having a gate terminal, a drain terminal, and a source terminal.

Here, a case in which an output impedance of the input power supply 61 is, for example, 50 [ohms] and an output impedance of the first radio frequency power supply 60 is, for example, 50 [ohms] is considered. An input impedance and an output impedance of the amplifier 63 are lower than the output impedance of the input power supply 61 and an impedance of the lower electrode 18 side from the output terminal 65 of the first radio frequency power supply 60, respectively. Therefore, impedance matching is required for an input and an output of the amplifier 63. The input impedance of the amplifier 63 corresponds to an impedance between the gate terminal and the source terminal, which are amplifier input terminals of the amplifier 63, and the output impedance of the amplifier 63 corresponds to an impedance between the drain terminal and the source terminal, which are amplifier output terminals of the amplifier 63. Therefore, the input-side transformer circuit 62 is connected between the input power supply 61 and the gate terminal of the amplifier 63. Further, the output-side transformer circuit 64 is connected between the drain terminal of the amplifier 63 and the output terminal 65.

That is, the input-side transformer circuit 62 is an impedance conversion circuit that performs impedance conversion between the output impedance of the input power supply 61 and the input impedance of the amplifier 63. Similarly, the output-side transformer circuit 64 is an impedance conversion circuit that performs impedance conversion between the output impedance of the amplifier 63 and the impedance of the output terminal 65 side (load side) of the first radio frequency power supply 60.

Next, impedance conversion using a transformer will be described with reference to FIG. 3. FIG. 3 is a diagram illustrating an example of impedance conversion by a transformer. As illustrated in FIG. 3, in impedance conversion of a parallel resonant circuit by a transformer, each parameter is set such that a square of turns ratio n between a primary side and a secondary side of the transformer becomes output impedance/input impedance. A relationship in which the square of the turns ratio n becomes output impedance/input impedance, that is, a relationship of R_{L}/Rₒ=n², is obtained based on a voltage e₁ and a current i₁ applied to the primary side of the transformer, a voltage e₂ and a current i₂ applied to the secondary side of the transformer, and the turns ratio n. Further, the turns ratio n of the transformer is given by n=N₂/N₁, where N₁ is the number of turns on the primary side and N₂ is the number of turns on the secondary side.

Here, Q₁ indicates a primary side Q factor of the transformer and is given by the following Equation (1). Further, Q₂ indicates a secondary side Q factor of the transformer and is given by the following Equation (2). In Equations (1) and (2), ω is a resonant angular frequency of the parallel resonant circuit.

Q₁=Rₒ/ωL₁ (1)

Q₂=R_{L}/ωL₂ (2)

In setting the parameters of the transformer, the primary side Q factor and the secondary side Q factor of the transformer are set to satisfy Q₁=Q₂. Therefore, inductances L₁ and L₂ of the transformer may be obtained from Equations (1) and (2), as represented in the following Equations (3) and (4).

$${L}_{1} = \frac{{R}_{0}}{ω} \sqrt{\frac{1}{{Q}_{1} \cdot {Q}_{2}}} \qquad ( 3 )$$

$${L}_{2} = {n}^{2} {L}_{1} \qquad ( 4 )$$

Capacitors C₁ and C₂ may be obtained by the following Equations (5) and (6) from a resonance condition of a parallel LC circuit.

C₁=1/(ω²L₁) (5)

C₂=1/(ω²L₂) (6)

Further, a mutual inductance M may be obtained by the following Equation (7) from the inductances L₁ and L₂ and a coupling coefficient k. Furthermore, a coupling index S, which is a parameter defined to determine element values of the input-side transformer circuit 62 and the output-side transformer circuit 64, is defined by the following Equation (8) from the coupling coefficient k and the primary side Q₁ and the secondary side Q₂ of the transformer. Further, Q₁ and Q₂ do not necessarily satisfy Q₁=Q₂ as long as the coupling index S and the coupling coefficient k fall within ranges to be described later. That is, Q₁ and Q₂ may allow, to some extent, errors in element values of the input-side transformer circuit 62 and the output-side transformer circuit 64.

M=k×\sqrt{L₁L₂} (7)

S=k/\sqrt{Q₁Q₂} (8)

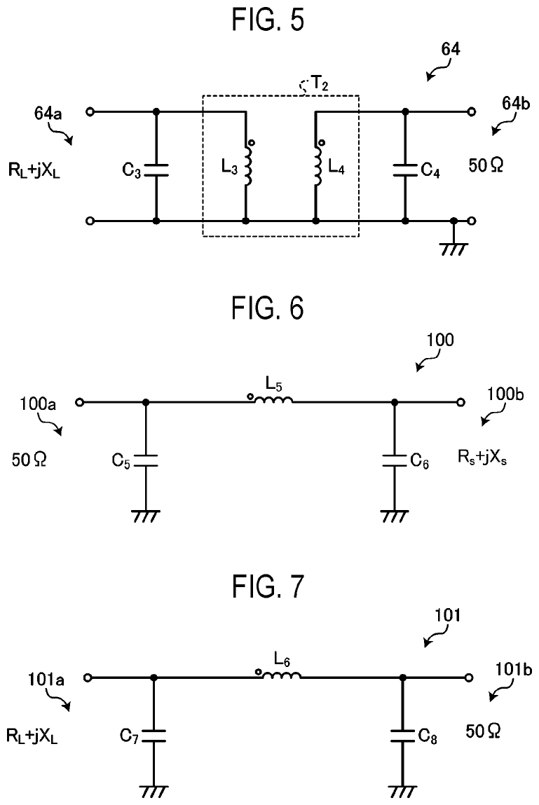

Next, the input-side transformer circuit 62 and the output-side transformer circuit 64 will be described with reference to FIGS. 4 and 5. FIG. 4 is a diagram illustrating an example of the input-side transformer circuit according to the present embodiment. As illustrated in FIG. 4, the input-side transformer circuit 62 includes a transformer T₁ and capacitors C₁ and C₂. In FIG. 4, an input-side inductance of the transformer T₁ is denoted by L₁, and an output-side inductance is denoted by L₂. The capacitor C₁ and the inductance L₁ are connected in parallel to an input terminal 62a, and an impedance of the input terminal 62a side is 50 [ohms]. The capacitor C₂ and the inductance L₂ are connected in parallel to an output terminal 62b, and an impedance of the output terminal 62b side is, for example, Rₛ+jXₛ [ohms]=1.99+j2.05 [ohms]−2.86 [ohms] when the frequency is 220 MHz. In other words, the impedance of the output terminal 62b side is set so as to match the input impedance between the gate terminal and the source terminal of the FET of the amplifier 63. Here, for example, when the coupling coefficient k is set to 0.9 and the coupling index S is set to 1, Q factors on the input side and the output side of the transformer T₁ become approximately Q₁=Q₂=1.1.

FIG. 5 is a diagram illustrating an example of an output-side transformer circuit according to the present embodiment. As illustrated in FIG. 5, the output-side transformer circuit 64 includes a transformer T₂ and capacitors C₃ and C₄. In FIG. 5, an input-side inductance of the transformer T₂ is denoted by L₃, and an output-side inductance is denoted by L₄. The capacitor C₃ and the inductance L₃ are connected in parallel to an input terminal 64a, and an impedance of the input terminal 64a side is, for example, R_{L}+jX_{L} [ohms]=0.65+j1.29 [ohms]=1.44 [ohms] when the frequency is 220 MHz. In other words, the impedance of the input terminal 64a side is set so as to match the output impedance between the drain terminal and the source terminal of the FET of the amplifier 63. The capacitor C₄ and the inductance L₄ are connected in parallel to an output terminal 64b, and the impedance of the output terminal 64b side is 50 [ohms]. Here, for example, when the coupling coefficient k is set to 0.9 and the coupling index S is set to 1, Q factors on the input side and the output side of the transformer T₂ become approximately Q₃=Q₄=1.1.

Capacitors (capacitors C₁ to C₄) are connected in parallel to the primary side and the secondary side of each of the input-side transformer circuit 62 and the output-side transformer circuit 64 so as to resonate within a range of at least±10% from the center frequency of the input power. In other words, parallel resonant circuits are formed respectively on the primary side and the secondary side of each of the input-side transformer circuit 62 and the output-side transformer circuit 64. Further, a primary side impedance of the input-side transformer circuit 62 is equal to a secondary side impedance of the output-side transformer circuit 64.

### [Comparison of Frequency Characteristics]

Next, frequency characteristics of the input-side transformer circuit 62 and the output-side transformer circuit 64 illustrated in FIGS. 4 and 5 are compared with frequency characteristics of an input-side pi-type matching circuit 100 and an output-side pi-type matching circuit 101 illustrated in FIGS. 6 and 7. First, the input-side pi-type matching circuit 100 and the output-side pi-type matching circuit 101 will be described with reference to FIGS. 6 and 7.

FIG. 6 is a diagram illustrating an example of an input-side pi-type matching circuit according to a reference example. As illustrated in FIG. 6, the input-side pi-type matching circuit 100 includes a coil L₅ and capacitors C₅ and C₆ that form a pi-type matching circuit. An impedance of the input terminal 100a side is 50 [ohms]. An impedance of the output terminal 100b side is, for example, Rₛ+jXₛ [ohms]=1.99+j2.05 [ohms]=2.86 [ohms] when the frequency is 220 MHz, which is the same as that of the input-side transformer circuit 62. In other words, the impedance of the output terminal 100b side is set so as to match the input impedance between the gate terminal and the source terminal of the FET of the amplifier 63.

FIG. 7 is a diagram illustrating an example of an output-side pi-type matching circuit according to a reference example. As illustrated in FIG. 7, the output-side pi-type matching circuit 101 includes a coil L₆ and capacitors C₇ and C₈ that form a pi-type matching circuit. An impedance of the input terminal 101a side is, for example, R_{L}+jX_{L} [ohms]−0.65+j1.29 [ohms]=1.44 [ohms] when the frequency is 220 MHz, which is the same as that of the output-side transformer circuit 64. In other words, the impedance of the input terminal 101a side is set so as to match the output impedance between the drain terminal and the source terminal of the FET of the amplifier 63. An impedance of the output terminal 101b side is 50 [ohms].

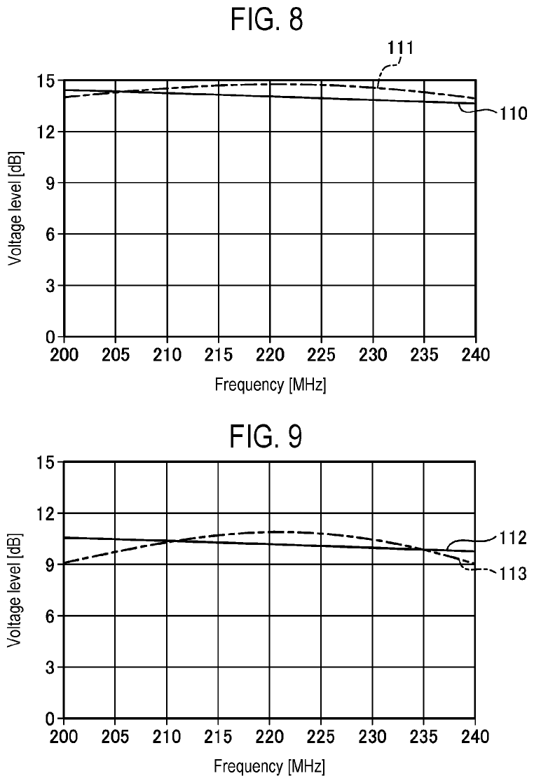

FIG. 8 is a graph indicating an example of frequency characteristics of input-side circuits. In FIG. 8, a graph 110 indicating frequency characteristics of the input-side transformer circuit 62 is compared with a graph 111 indicating frequency characteristics of the input-side pi-type matching circuit 100. A vertical axis of the graph in FIG. 8 represents a voltage level applied to a load when a current source of 1 [A] is connected. Further, a horizontal axis of the graph in FIG. 8 represents a frequency of input power. FIG. 8 illustrates frequency characteristics within a range of +20 MHz from the center frequency of 220 MHZ, and it can be recognized that the graph 110 has flatter frequency characteristics than the graph 111. That is, the input-side transformer circuit 62 has flatter frequency characteristics than the input-side pi-type matching circuit 100.

FIG. 9 is a graph indicating an example of frequency characteristics of output-side circuits. In FIG. 9, a graph 112 indicating frequency characteristics of the output-side transformer circuit 64 is compared with a graph 113 indicating frequency characteristics of the output-side pi-type matching circuit 101. A vertical axis of the graph in FIG. 9 represents a voltage level applied to a load when a current source of 1 [A] is connected. Further, a horizontal axis of the graph in FIG. 9 represents a frequency of input power (corresponding to an output of the FET). FIG. 9 illustrates frequency characteristics within a range of +20 MHz from the center frequency of 220 MHz, and it can be recognized that the graph 112 has flatter frequency characteristics than the graph 113. That is, the output-side transformer circuit 64 has flatter frequency characteristics than the output-side pi-type matching circuit 101. In other words, as illustrated in FIGS. 8 and 9, the input-side transformer circuit 62 and the output-side transformer circuit 64 may make the frequency characteristics of the FET flatter than the input-side pi-type matching circuit 100 and the output-side pi-type matching circuit 101.

### [Comparison of Efficiency and Output Characteristics]

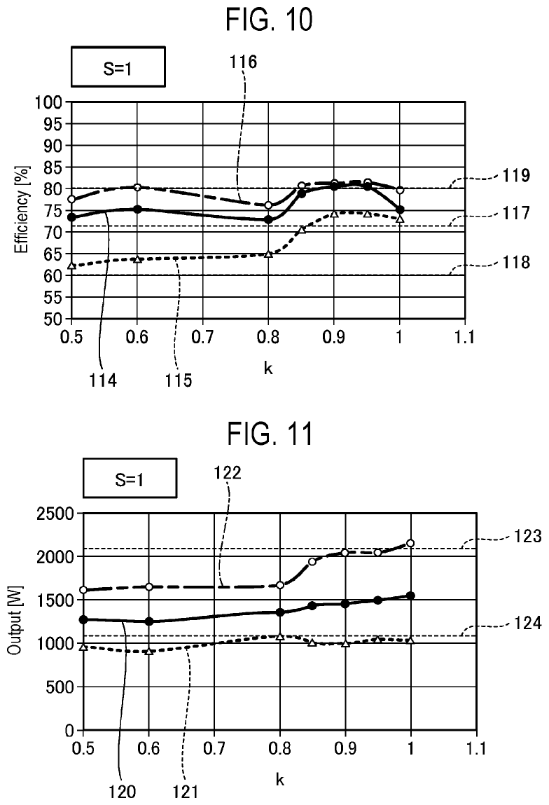

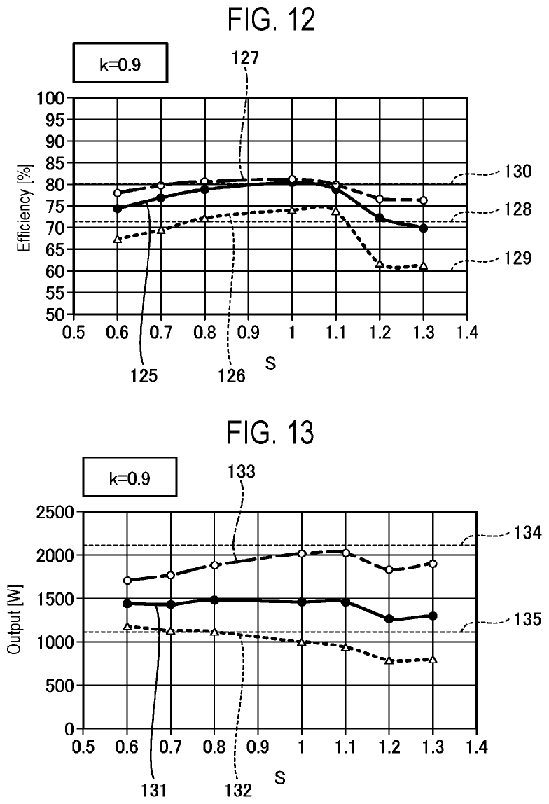

Next, efficiency and output characteristics in a case where transformer circuits are used respectively on the input side and the output side and the frequency is varied by ±10% from the center frequency of 220 MHz, and where the coupling index S=1 and the coupling coefficient k is variable will be described with reference to FIGS. 10 and 11. Further, efficiency and output characteristics in a case where transformer circuits are used respectively on the input side and the output side and the frequency is varied by ±10% (approximately ±20 MHz) from the center frequency of 220 MHz, and where the coupling coefficient k=0.9 and the coupling index S is variable will be described with reference to FIGS. 12 and 13. FIGS. 10 to 13 also illustrate efficiencies or outputs when pi-type matching circuits are used respectively on the input side and the output side and the frequency is varied by ±10% (approximately ±20 MHz) from the center frequency of 220 MHz. In other words, FIGS. 10 to 13 illustrate an efficiency or an output at the center frequency when pi-type matching circuits are used respectively on the input side and the output side. Further, FIGS. 10 to 13 illustrate an efficiency value or an output value at a frequency where the efficiency or the output becomes maximum, and an efficiency value or an output value at a frequency where the efficiency or the output becomes minimum, when pi-type matching circuits are used respectively on the input side and the output side. In addition, in descriptions of FIGS. 10 to 20, the input-side transformer circuit 62 and the output-side transformer circuit 64 may simply be referred to as a “transformer circuit,” and the input-side pi-type matching circuit 100 and the output-side pi-type matching circuit 101 may simply be referred to as a “pi-type matching circuit.”

FIG. 10 is a graph illustrating an example of efficiencies of the first radio frequency power supply when the coupling index S is constant and the coupling coefficient k and the frequency are variable. A graph 114 illustrated in FIG. 10 indicates a correspondence between the coupling coefficient k and an efficiency of the first radio frequency power supply 60 at the center frequency (220 MHz) of the transformer circuit. A graph 115 indicates a correspondence between the coupling coefficient k and a minimum efficiency of the first radio frequency power supply 60 within a ±10% range from the center frequency of the transformer circuit. In other words, the graph 115 plots minimum efficiencies, each being a minimum efficiency of the first radio frequency power supply 60 within the +10% range from the center frequency at a corresponding coupling coefficient k. A graph 116 indicates a correspondence between the coupling coefficient k and a maximum efficiency of the first radio frequency power supply 60 within a ±10% range from the center frequency of the transformer circuit. In other words, the graph 116 plots maximum efficiencies, each being a maximum efficiency of the first radio frequency power supply 60 within the +10% range from the center frequency at a corresponding coupling coefficient k.

An efficiency value 117 is an efficiency value of the pi-type matching circuit at the center frequency. An efficiency value 118 is an efficiency value of the pi-type matching circuit at a frequency at which the efficiency becomes minimum. An efficiency value 119 is an efficiency value of the pi-type matching circuit at a frequency at which the efficiency becomes maximum. As indicated in the graphs 114 to 116 and the efficiency values 117 to 119, the graph 115 of the transformer circuit is improved relative to the efficiency value 118 when the coupling coefficient k is within a range of 0.85 to 1. In other words, when the coupling coefficient k is in the range of 0.85 or more and 1 or less, the graph 115 indicating the minimum efficiency of the transformer circuit is significantly improved relative to the efficiency value 118 indicating the minimum efficiency of the pi-type matching circuit.

FIG. 11 is a graph illustrating an example of outputs of the first radio frequency power supply when the coupling index S is constant and the coupling coefficient k and the frequency are variable. A graph 120 illustrated in FIG. 11 indicates a correspondence between the coupling coefficient k and an output of the first radio frequency power supply 60 at the center frequency (220 MHz) of the transformer circuit. A graph 121 indicates a correspondence between the coupling coefficient k and a minimum output of the first radio frequency power supply 60 within a ±10% range from the center frequency of the transformer circuit. In other words, the graph 121 plots minimum outputs, each being a minimum output of the first radio frequency power supply 60 within the +10% range of the center frequency at a corresponding coupling coefficient k. A graph 122 indicates a correspondence between the coupling coefficient k and a maximum output of the first radio frequency power supply 60 within a ±10% range from the center frequency of the transformer circuit. In other words, the graph 122 plots maximum outputs, each being a maximum output of the first radio frequency power supply 60 within the +10% range from the center frequency at a corresponding coupling coefficient k.

An output value 123 is an output value of the pi-type matching circuit at the center frequency. An output value 124 is an output value of the pi-type matching circuit at a frequency at which the output becomes minimum. As indicated in the graphs 120 to 122 and the output values 123 and 124, the minimum outputs of the transformer circuit indicated in the graph 121 are approximately the same as the output value 124, which is the minimum output value of the pi-type matching circuit.

FIG. 12 is a graph illustrating an example of efficiencies of the first radio frequency power supply when the coupling coefficient k is constant and the coupling index S and frequency are variable. A graph 125 illustrated in FIG. 12 indicates a correspondence between the coupling index S and an efficiency of the first radio frequency power supply 60 at the center frequency (220 MHz) of the transformer circuit. A graph 126 indicates a correspondence between the coupling index S and a minimum efficiency of the first radio frequency power supply 60 within a ±10% range from the center frequency of the transformer circuit. In other words, the graph 126 plots minimum efficiencies, each being a minimum efficiency of the first radio frequency power supply 60 within the +10% range from the center frequency at a corresponding coupling index S. A graph 127 indicates a correspondence between the coupling index S and a maximum efficiency of the first radio frequency power supply 60 within a ±10% range from the center frequency of the transformer circuit. In other words, the graph 127 plots maximum efficiencies, each being a maximum efficiency of the first radio frequency power supply 60 within the +10% range from the center frequency at a corresponding coupling index S.

An efficiency value 128 is an efficiency value of the pi-type matching circuit at the center frequency. An efficiency value 129 is an efficiency value of the pi-type matching circuit at a frequency at which the efficiency becomes minimum. An efficiency value 130 is an efficiency value of the pi-type matching circuit at a frequency at which the efficiency becomes maximum. As indicated in the graphs 125 to 127 and the efficiency values 128 to 130, the graph 126 of the transformer circuit is improved relative to the efficiency value 129. In other words, the graph 126 indicating the minimum efficiency of the transformer circuit is improved relative to the efficiency value 129 indicating the minimum efficiency of the pi-type matching circuit. Further, the graph 125 of the transformer circuit is improved relative to the efficiency value 128. In other words, the graph 125 indicating the efficiency of the transformer circuit at the center frequency is improved relative to the efficiency value 128 indicating the efficiency of the pi-type matching circuit at the center frequency.

FIG. 13 is a graph illustrating an example of outputs of the first radio frequency power supply when the coupling coefficient k is constant and the coupling index S and frequency are variable. A graph 131 illustrated in FIG. 13 indicates a correspondence between the coupling index S and an output of the first radio frequency power supply 60 at the center frequency (220 MHz) of the transformer circuit. A graph 132 indicates a correspondence between the coupling index S and a minimum output of the first radio frequency power supply 60 within a ±10% range from the center frequency of the transformer circuit. In other words, the graph 132 plots minimum outputs, each being a minimum output of the first radio frequency power supply 60 within the ±10% range from the center frequency at a corresponding coupling index S. A graph 133 indicates a correspondence between the coupling index S and a maximum output of the first radio frequency power supply 60 within a ±10% range from the center frequency of the transformer circuit. In other words, the graph 133 plots maximum outputs, each being a maximum output of the first radio frequency power supply 60 within the ±10% range from the center frequency at a corresponding coupling index S.

An output value 134 is an output value of the pi-type matching circuit at the center frequency. An output power value 135 is an output value of the pi-type matching circuit at a frequency at which the output becomes minimum. As indicated in the graphs 131 to 133 and the output values 134 and 135, the minimum outputs of the transformer circuit indicated in the graph 132 are approximately the same as the output value 135, which is the minimum output of the pi-type matching circuit, within a range in which the coupling index S exceeds 0.8.

[Optimal Values of Coupling Index S and Coupling Coefficient k]

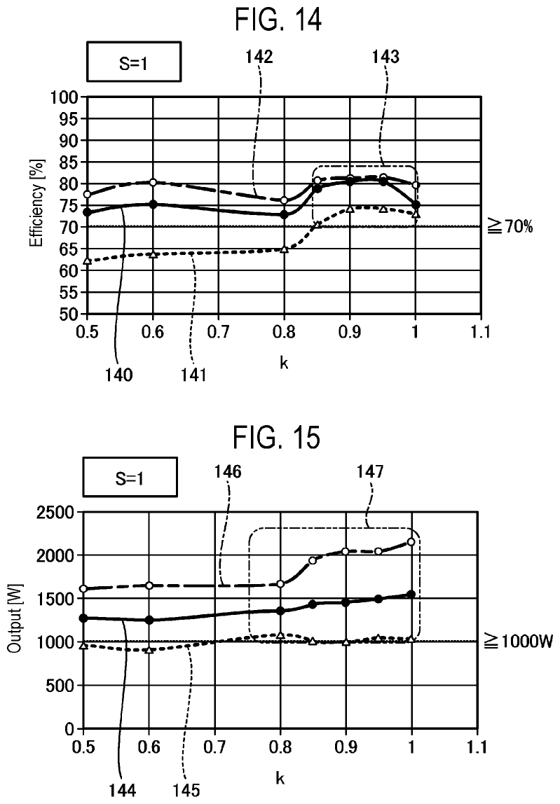

Next, optimal values of the coupling index S and the coupling coefficient k in the input-side transformer circuit 62 and the output-side transformer circuit 64 will be reviewed with reference to FIGS. 14 to 17.

FIG. 14 is a graph illustrating an example of a range of an optimal value of the coupling coefficient k within which the efficiencies become 70% or more, when the coupling index S is constant and the coupling coefficient k and frequency are variable. Graphs 140 to 142 illustrated in FIG. 14 correspond to the graphs 114 to 116 illustrated in FIG. 10. That is, the graph 140 indicates the correspondence between the coupling coefficient k and the efficiency of the first radio frequency power supply 60 at the center frequency (220 MHz) of the transformer circuit. The graph 141 plots minimum efficiencies, each being a minimum efficiency of the first radio frequency power supply 60 within a ±10% range from the center frequency at the corresponding coupling coefficient k. The graph 142 plots maximum efficiencies, each being a maximum efficiency of the first radio frequency power supply 60 within a ±10% range from the center frequency at the corresponding coupling coefficient k. Here, considering a range within which the efficiencies of the first radio frequency power supply 60 are 70% or more to be the range of the optimal value, a range 143 of 0.85 or more and 1 or less is obtained as the range of the optimal value of the coupling coefficient k in terms of efficiency.

FIG. 15 is a graph indicating an example of a range of an optimal value of the coupling coefficient k within which the outputs become 1,000 W or more, when the coupling index S is constant and the coupling coefficient k and frequency are variable. Graphs 144 to 146 illustrated in FIG. 15 correspond to the graphs 120 to 122 illustrated in FIG. 11. That is, the graph 144 indicates the correspondence between the coupling coefficient k and the output of the first radio frequency power supply 60 at the center frequency (220 MHz) of the transformer circuit. The graph 145 plots minimum outputs, each being a minimum output of the first radio frequency power supply 60 within a ±10% range from the center frequency at the corresponding coupling coefficient k. The graph 146 plots maximum outputs, each being a maximum output of the first radio frequency power supply 60 within a ±10% range from the center frequency at the corresponding coupling coefficient k. Here, considering a range in which the outputs of the first radio frequency power supply 60 are 1,000 W or more to be the range of the optimal value, a range 147 of 0.8 or more and 1 or less is obtained as the range of the optimal value of the coupling coefficient k in terms of output.

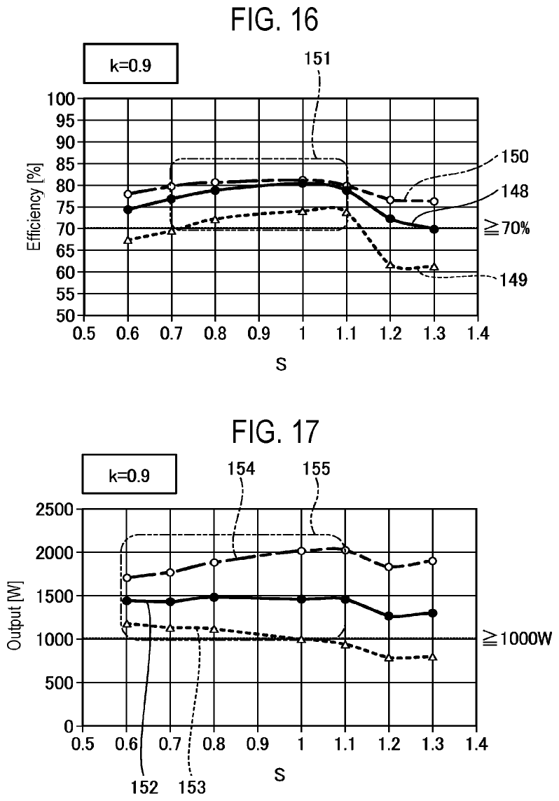

FIG. 16 is a graph indicating an example of a range of an optimal value of the coupling index S within which the efficiencies become 70% or more, when the coupling coefficient k is constant and the coupling index S and frequency are variable. Graphs 148 to 150 illustrated in FIG. 16 correspond to the graphs 125 to 127 illustrated in FIG. 12. That is, the graph 148 indicates the correspondence between the coupling index S and the efficiency of the first radio frequency power supply 60 at the center frequency (220 MHZ) of the transformer circuit. The graph 149 plots minimum efficiencies, each being a minimum efficiency of the first radio frequency power supply 60 within a ±10% range from the center frequency at the corresponding coupling index S. The graph 150 plots maximum efficiencies, each being a maximum efficiency of the first radio frequency power supply 60 within a ±10% range from the center frequency at the corresponding coupling index S. Here, considering a range within which the efficiencies of the first radio frequency power supply 60 are 70% or more to be the range of the optimal value, a range 151 of 0.8 or more and 1.1 or less is obtained as the range of the optimal value of the coupling index S in terms of efficiency.

FIG. 17 is a graph illustrating an example of a range of an optimal value of the coupling index S within which the outputs become 1,000 W or more, when the coupling coefficient k is constant and the coupling index S and frequency are variable. Graphs 152 to 154 illustrated in FIG. 17 correspond to the graphs 131 to 133 illustrated in FIG. 13. That is, the graph 152 indicates the correspondence between the coupling index S and the output of the first radio frequency power supply 60 at the center frequency (220 MHZ) of the transformer circuit. The graph 153 plots minimum outputs, each being a minimum output of the first radio frequency power supply 60 within a ±10% range from the center frequency at the corresponding coupling index S. The graph 154 plots maximum outputs, each being a maximum output of the first radio frequency power supply 60 within a ±10% range from the center frequency at the corresponding coupling index S. Here, considering a range within which the outputs of the first radio frequency power supply 60 are 1,000 W or more to be the range of the optimal value, a range 155 of 1 or less is obtained as the range of the optimal value of the coupling index S in terms of output. In addition, prioritizing the range of optimal value in terms of efficiency indicated by the range 151 in FIG. 16, “1.1” may be adopted as an upper limit of the range of the optimal value of the coupling index S.

From FIGS. 14 to 17, ranges of optimal values of the coupling index S and the coupling coefficient k in the input-side transformer circuit 62 and the output-side transformer circuit 64 satisfy the following Equations (9) and (10), respectively.

0.8≤S≤1.1 (9)

0.85≤k≤1 (10)

### [Efficiency When Varying Center Frequency]

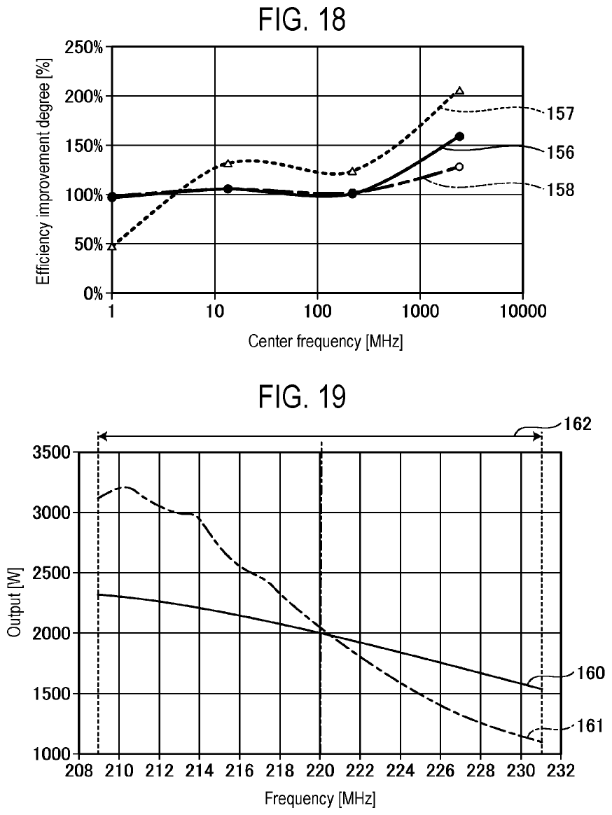

FIG. 18 is a graph indicating an example of a relationship between a center frequency and a degree of improvement in efficiency. A graph 156 illustrated in FIG. 18 indicates an efficiency improvement degree of the transformer circuit relative to the pi-type matching circuit at the center frequency, when the center frequency of the transformer circuit is varied. A graph 157 plots efficiency improvement degrees, each being a degree of improvement in minimum efficiency of the first radio frequency power supply 60 relative to the pi-type matching circuit within a ±10% range from a corresponding center frequency, when the center frequency of the transformer circuit is varied. A graph 158 plots the efficiency improvement degrees, each being a degree of improvement in maximum efficiency of the first radio frequency power supply 60 relative to the pi-type matching circuit within a ±10% range from a corresponding center frequency, when the center frequency of the transformer circuit is varied. In addition, the efficiency improvement degree is obtained by the following Equation (11).

Efficiency improvement degree[%]=Efficiency of transformer circuit/Efficiency of pi-type matching circuit (11)

From the graphs 156 to 158, in the input-side transformer circuit 62 and the output-side transformer circuit 64, the minimum efficiency is improved relative to the pi-type matching circuit when the center frequency exceeds approximately 10 MHz. In particular, the minimum efficiency is significantly improved relative to the pi-type matching circuit when the center frequency exceeds 1,000 MHz.

[Output and Efficiency within ±5% Range from Center Frequency]

FIG. 19 is a graph indicating an example of a relationship between a frequency and an output. A graph 160 illustrated in FIG. 19 indicates an output of the transformer circuit within a range 162, which is a range of +5% (209 MHz to 231 MHz) from a center frequency (220 MHz). A graph 161 indicates an output of the pi-type matching circuit within the range 162 of +5% (209 MHz to 231 MHz) from the center frequency (220 MHz). Parameters of the amplifier 63 are, for example, a gate bias voltage V_{g}=2.1 V, a drain bias voltage V_{d}=75 V, and an input power Pᵢₙ=42.6 dBm. It can be recognized from comparison of the graphs 160 and 161 that decrease in the output at high frequencies within the range 162 is smaller when the transformer circuit is used than when the pi-type matching circuit is used.

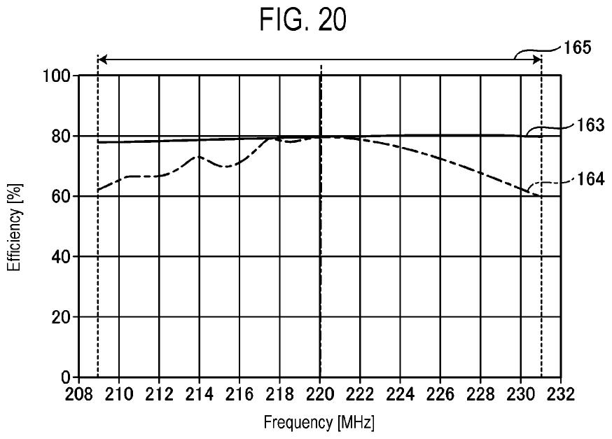

FIG. 20 is a graph indicating an example of a relationship between a frequency and an efficiency. A graph 163 illustrated in FIG. 20 indicates an efficiency of the transformer circuit within a range 165, which is a range of +5% (209 MHz to 231 MHz) from a center frequency (220 MHz). A graph 164 indicates an efficiency of the pi-type matching circuit within the range 165 of +5% (209 MHz to 231 MHz) from the center frequency (220 MHz). Parameters of the amplifier 63 are the same as those in FIG. 19. It can be recognized from comparison of the graphs 163 and 164 that the efficiency within the range 165 is flatter when the transformer circuit is used than when the pi-type matching circuit is used.

As described above, in the present embodiment, the first radio frequency power supply 60 can vary the frequency relative to the fundamental frequency, thereby reducing reflected waves caused by impedance mismatch during plasma generation. That is, the first radio frequency power supply 60 can reduce reflected waves by tuning the frequency at high speed, thereby improving the efficiency of input power for plasma generation and reducing environmental loads. Further, since the first radio frequency power supply 60 maintains a high efficiency not only at the fundamental frequency but also within the variable frequency range, an output can exceed a rated output. In other words, the first radio frequency power supply 60 can reduce loss in a power amplifier during impedance matching by varying frequency during plasma generation.

According to the present embodiment, a radio frequency power supply for plasma generation (the first radio frequency power supply 60) includes the amplifier 63, the input power supply 61, the output terminal 65, the input-side transformer circuit 62, and the output-side transformer circuit 64. The amplifier 63 includes a gate terminal, a drain terminal, and a source terminal of an FET. An amplifier input terminal of the amplifier 63 corresponds to the gate terminal and the source terminal, and an amplifier output terminal of the amplifier 63 corresponds to the drain terminal and the source terminal. The input power supply 61 is electrically connected to the gate terminal to supply input power to the amplifier 63, and is configured to vary a supply frequency of the input power within an available supply frequency band. The output terminal 65 is electrically connected to the drain terminal. The input-side transformer circuit 62 is connected between the input power supply 61 and the gate terminal. The output-side transformer circuit 64 is connected between the drain terminal and the output terminal 65. As a result, the first radio frequency power supply 60 can reduce loss in a power amplifier (the amplifier 63) during impedance matching by varying the frequency during plasma generation. In addition, the source terminal of the amplifier 63 is grounded, and is connected to the ground of the input power supply 61 and the ground of the output terminal 65.

According to the present embodiment, the input-side transformer circuit 62 is an impedance conversion circuit that performs impedance conversion between the input power supply 61 and the gate terminal. As a result, the first radio frequency power supply 60 can reduce reflected waves caused by impedance mismatch, thereby efficiently supplying input power to the amplifier 63.

According to the present embodiment, the output-side transformer circuit 64 is an impedance conversion circuit that performs impedance conversion between the drain terminal and the output terminal 65. As a result, the first radio frequency power supply 60 can reduce reflected waves caused by impedance mismatch, thereby efficiently outputting power amplified by the amplifier 63 from the output terminal 65.

According to the present embodiment, a value defined as the coupling index S of each of the input-side transformer circuit 62 and the output-side transformer circuit 64 satisfies Equation (9). However, in Equation (9), the coupling index S is defined by Equation (8). As a result, the efficiency and output characteristics of the first radio frequency power supply 60 can be improved even when the frequency is varied from the fundamental frequency (center frequency).

According to the present embodiment, the coupling coefficient k of each of the input-side transformer circuit 62 and the output-side transformer circuit 64 is within a range of 0.85≤k≤1. As a result, the first radio frequency power supply 60 can output power having a desired efficiency and output even under conditions where the efficiency and the output become minimum within a variable frequency range.

According to the present embodiment, the primary side Q factor and the secondary side Q factor of each of the input-side transformer circuit 62 and the output-side transformer circuit 64 satisfy a relationship of Q₁=Q₂. As a result, the first radio frequency power supply 60 can make the frequency characteristics of the input-side transformer circuit 62 and the output-side transformer circuit 64 be uniform.

According to the present embodiment, capacitors (the capacitors C₁ to C₄) are connected in parallel to the primary side and the secondary side of each of the input-side transformer circuit 62 and the output-side transformer circuit 64 so as to resonate within a range of at least±10% from the center frequency of the input power. As a result, the first radio frequency power supply 60 can set the Q factors of parallel resonant circuits on the primary side and secondary side of each of the input-side transformer circuit 62 and the output-side transformer circuit 64.

According to the present embodiment, the center frequency of the input power supplied by the input power supply 61 is within a range of 10 MHz to 2,450 MHZ, and the center frequency of the radio frequency power output from the output terminal 65 is within the range of 10 MHz to 2,450 MHz. As a result, the first radio frequency power supply 60 can supply radio frequency power having a center frequency within the range of 10 MHz to 2,450 MHz.

According to the present embodiment, the primary side impedance of the input-side transformer circuit 62 is equal to the secondary side impedance of the output-side transformer circuit 64. As a result, the first radio frequency power supply 60 can make the impedance before and after the amplifier 63 be uniform, thereby reducing reflected waves.

The embodiments disclosed herein should be considered to be illustrative and not restrictive in all respects. The above embodiments may be omitted, substituted, or modified in various ways without departing from the scope and spirit of the appended claims.

Further, in the above embodiments, the plasma processing apparatus 1 that performs processing such as etching on the substrate W by using capacitively coupled plasma as a plasma source has been described by way of example, but the disclosed technique is not limited thereto. The plasma processing apparatus may perform processing such as a film formation, as long as the apparatus performs the processing on the substrate W by using plasma and uses a radio frequency power supply. Further, the plasma source is not limited to capacitively coupled plasma, and may be any plasma source such as inductively coupled plasma, microwave plasma or magnetron plasma may.

The present disclosure may also adopt the following configurations.
(1) A radio frequency power supply for plasma generation, including:
   an amplifier having a gate terminal, a drain terminal, and a source terminal;
   an input power supply electrically connected to the gate terminal to supply input power to the amplifier, and configured to vary a supply frequency of the input power within an available supply frequency band;
   an output terminal electrically connected to the drain terminal;
   an input-side transformer circuit connected between the input power supply and the gate terminal; and
   an output-side transformer circuit connected between the drain terminal and the output terminal.
(2) The radio frequency power supply for plasma generation of (1), wherein the input-side transformer circuit is an impedance conversion circuit that performs impedance conversion between the input power supply and the gate terminal.
(3) The radio frequency power supply for plasma generation of (1) or (2), wherein the output-side transformer circuit is an impedance conversion circuit that performs impedance conversion between the drain terminal and the output terminal.
(4) The radio frequency power supply for plasma generation of any one of (1) to (3), wherein a value defined as a coupling index S of each of the input-side transformer circuit and the output-side transformer circuit satisfies the following Equation (1):

0.8≤S≤1.1 (1),

where the coupling index S is defined by the following Equation (2):

S=k/\sqrt{Q₁Q₂} (2),

where k indicates a coupling coefficient of the input-side transformer circuit or the output-side transformer circuit, Q₁ indicates a primary side Q factor of the input-side transformer circuit or the output-side transformer circuit, and Q₂ indicates a secondary side Q factor of the input-side transformer circuit or the output-side transformer circuit.
(5) The radio frequency power supply for plasma generation of (4), wherein the coupling coefficient of each of the input-side transformer circuit and the output-side transformer circuit is within a range of 0.85≤k≤1.
(6) The radio frequency power supply for plasma generation of (4) or (5), wherein the primary side Q factor and the secondary side Q factor of each of the input-side transformer circuit and the output-side transformer circuit satisfy a relationship of Q₁=Q₂.
(7) The radio frequency power supply for plasma generation of any one of (1) to (6), wherein capacitors are connected in parallel to a primary side and a secondary side of each of the input-side transformer circuit and the output-side transformer circuit so as to resonate within a range of at least±10% from a center frequency of the input power.
(8) The radio frequency power supply for plasma generation of any one of (1) to (7), wherein a center frequency of the input power supplied by the input power supply is within a range of 10 MHz to 2,450 MHZ, and wherein a center frequency of radio frequency power output from the output terminal is within a range of 10 MHz to 2,450 MHz.
(9) The radio frequency power supply for plasma generation of any one of (1) to (8), wherein a primary side impedance of the input-side transformer circuit is equal to a secondary side impedance of the output-side transformer circuit.
(10) A plasma processing apparatus including:
   a processing container;
   an electrode provided in the processing container;
   and a radio frequency power supply configured to output radio frequency power having a set frequency to the electrode,
   wherein the radio frequency power supply includes:
      an amplifier having a gate terminal, a drain terminal, and a source terminal;
      an input power supply electrically connected to the gate terminal to supply input power to the amplifier, and configured to vary a supply frequency of the input power within an available supply frequency band;
      an output terminal electrically connected to the electrode and the drain terminal;
      an input-side transformer circuit connected between the input power supply and the gate terminal; and
      an output-side transformer circuit connected between the drain terminal and the output terminal.

According to the present disclosure, it is possible to reduce loss in a power amplifier during impedance matching by varying a frequency during plasma generation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A radio frequency power supply for plasma generation, comprising:
an amplifier having a gate terminal, a drain terminal, and a source terminal;
an input power supply electrically connected to the gate terminal to supply input power to the amplifier, and configured to vary a supply frequency of the input power within an available supply frequency band;
an output terminal electrically connected to the drain terminal;
an input-side transformer circuit connected between the input power supply and the gate terminal; and
an output-side transformer circuit connected between the drain terminal and the output terminal.

2. The radio frequency power supply for plasma generation of claim 1, wherein the input-side transformer circuit is an impedance conversion circuit that performs impedance conversion between the input power supply and the gate terminal.

3. The radio frequency power supply for plasma generation of claim 2, wherein the output-side transformer circuit is an impedance conversion circuit that performs impedance conversion between the drain terminal and the output terminal.

4. The radio frequency power supply for plasma generation of claim 1, wherein the output-side transformer circuit is an impedance conversion circuit that performs impedance conversion between the drain terminal and the output terminal.

5. The radio frequency power supply for plasma generation of claim 1, wherein a value defined as a coupling index S of each of the input-side transformer circuit and the output-side transformer circuit satisfies the following Equation (1):
0.8≤S≤1.1 (1)
where the coupling index S is defined by the following Equation (2):
S=k/Q₁Q₂ (2),
where k indicates a coupling coefficient of the input-side transformer circuit or the output-side transformer circuit, Q₁ indicates a primary side Q factor of the input-side transformer circuit or the output-side transformer circuit, and Q₂ indicates a secondary side Q factor of the input-side transformer circuit or the output-side transformer circuit.

6. The radio frequency power supply for plasma generation of claim 5, wherein the coupling coefficient of each of the input-side transformer circuit and the output-side transformer circuit is within a range of 0.85≤k≤1.

7. The radio frequency power supply for plasma generation of claim 5, wherein the primary side Q factor and the secondary side Q factor of each of the input-side transformer circuit and the output-side transformer circuit satisfy a relationship of Q₁=Q₂.

8. The radio frequency power supply for plasma generation of claim 1, wherein capacitors are connected in parallel to a primary side and a secondary side of each of the input-side transformer circuit and the output-side transformer circuit so as to resonate within a range of at least±10% from a center frequency of the input power.

9. The radio frequency power supply for plasma generation of claim 1, wherein a center frequency of the input power supplied by the input power supply is within a range of 10 MHz to 2,450 MHz, and
wherein a center frequency of radio frequency power output from the output terminal is within a range of 10 MHz to 2,450 MHz.

10. The radio frequency power supply for plasma generation of claim 1, wherein a primary side impedance of the input-side transformer circuit is equal to a secondary side impedance of the output-side transformer circuit.

11. A plasma processing apparatus comprising:
a processing container;
an electrode provided in the processing container; and
a radio frequency power supply configured to output radio frequency power having a set frequency to the electrode,
wherein the radio frequency power supply includes:
an amplifier having a gate terminal, a drain terminal, and a source terminal;
an input power supply electrically connected to the gate terminal to supply input power to the amplifier, and configured to vary a supply frequency of the input power within an available supply frequency band;
an output terminal electrically connected to the electrode and the drain terminal;
an input-side transformer circuit connected between the input power supply and the gate terminal; and
an output-side transformer circuit connected between the drain terminal and the output terminal.
